(19) United States
(12) Patent Application Publication
(10) Pub. No.: US 2005/0196962 A1
(43) Pub. Date: Sep. 8, 2005

(54) Method for forming a self-aligned germanide and devices obtained thereof

(75) Inventors: Caroline Demeurisse, Leuven (BE); Karl Opsomer, Gavere (BE)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: Interuniversitair Microelektronica Centrum (IMEC), Leuven (BE)

(21) Appl. No.: 11/079,022

(22) Filed: Mar. 8, 2005

Related U.S. Application Data
(60) Provisional application No. 60/551,543, filed on Mar. 8, 2004.

(51) Int. Cl. H01L 21/336; H01L 21/461; H01L 21/302

(52) U.S. Cl. 438/689

(57) ABSTRACT

A method for removing unreacted metal from a germanium layer, a germanide layer and or a dielectric material. The method includes removing the unreacted metal using a chemical composition that includes one or more hydrohalides, such as in an aqueous form. In certain embodiments, the chemical composition may also include H₂SO₄. Also, in certain embodiments, the chemical composition may be heated to increase the etch rate of the unreacted metal and/or improve the etch selectivity to the germanium, the germanide and/or the dielectric material.

### CROSS REFERENCE TO RELATED APPLICATIONS

This application claims benefits under 35 U.S.C. § 119(e) to U.S. Provisional Patent Application 60/551,543, filed on Mar. 8, 2004. The entire disclosure of Provisional Application 60/551,543 is herein incorporated by reference.

### FIELD

This invention is related to the field of semiconductor processing and, more specifically, to the field of forming germanides, compounds of germanium and metal, in a self-aligned way. This invention is also related to chemical compositions for selectively removing unreacted metal in such processes.

### BACKGROUND

An approach for modifying the electronic properties of a semiconductor element (e.g. to reduce the resistivity of a semiconductor region in a substrate, so as to change the work-function of a semiconductor gate electrode formed upon this substrate) is to deposit a metal over at least the particular semiconductor element. The stack that includes the metal and the semiconductor material is then heated to produce a semiconductor-metal compound layer. This layer has a lower resistivity than the resistivity of the starting semiconductor material and, thus, has a different work-function. Unreacted metal is then removed from the substrate, such as selectively from the semiconductor-metal compound. Such a process leaves the semiconductor-metal compound layer intact and removes excess unreacted metal from the deposition and heating operations. The semiconductor layers formed by such processes may be referred to as semiconductor metalide layers.

A semiconductor metalide layer that is obtained by selectively removing unreacted metal without performing any subsequent masking step to pattern the metalide layer is typically referred to as a self-aligned structure. In certain embodiments, an additional heating step is performed to further reduce the resistivity of the semiconductor metalide layer, e.g. by changing the crystal phase of this layer.

Examples of such semiconductor-metal compounds are silicides. Metal silicide thin films are commonly used in microelectronic circuits in a variety of applications, such as interconnects, contacts and for the formation of transistor gates. For example, Titanium disilicide (TiSi₂), Cobalt disilicide (CoSi₂), and/or Nickel silicide (NiSi) are used in Ultra Large Scale Integration Semiconductor devices having submicron feature sizes. As is known, silicide layers have a lower sheet resistance than the corresponding sheet resistance of the silicon from which they are formed.

Due to its electronic properties, germanium is, for various MOS technologies, considered to be a replacement for silicon as the semiconductor material of choice to form substrates and/or gate electrodes. Germanides, e.g. compounds resulting from the reaction between germanium and a metal, such as Ni, are used to reduce the resistivity of source and drain regions, or to reduce the resistivity of gate electrodes and, thus, modify the work-function of the gate electrodes. However, current approaches do not provide for selective removal of unreacted metal to produce self-aligned germanides.

### SUMMARY

Methods for removing unreacted metal from germanium layers, germanide layers, and/or dielectric layers, such as to form self-aligned germanides, are disclosed. Further, compositions for removing such unreacted metal are described.

A composition for removing unreacted metal, e.g. Ni, from a germanium layer, a germanide layer and/or a dielectric layer includes one or more hydrohalides, e.g. HCl. The composition may also further comprise H₂SO₄, which allows for the removal of unreacted metals without heating. The composition is used to remove unreacted metal(s) that are used to form a self-aligned metal-germanide compound. Such metals include Ti, Co, Pt, Pd and Ru, among others.

A method for forming a self-aligned germanide comprises selectively removing unreacted metal(s) from a germanium layer, a germanide layer and/or a dielectric layer, by contacting said unreacted metal(s) with a chemical composition, heated or not, that includes one or more hydrohalides. As noted above, the composition may further include H₂SO₄. Using such compositions and methods, a semiconductor device including a self-aligned germanide layer (from which unreacted metal has been removed) may be formed.

### BRIEF DESCRIPTION OF THE DRAWINGS

Various embodiments are described herein with reference to the following drawings. Certain aspects of the drawings are depicted in a simplified way for reason of clarity. Not all alternatives and options are shown in the drawings and, therefore, the invention is not limited in scope to the content of the drawings. Like numerals are employed to reference like parts in the different figures, in which:

FIGS. 1A-1D are cross-sectional drawings that illustrate a semiconductor device structure before, during and after formation of self-aligned germanide;

FIGS. 2A-2E are cross-sectional drawings that illustrate another semiconductor device structure before, during and after formation of self-aligned germanide;

FIGS. 3A and 3B are graphs that illustrate sheet resistance as a function of annealing temperature for germanides formed on undoped germanium (FIG. 3A) and doped germanium (FIG. 3B);

FIGS. 4A and 4B are graphs that illustrates etch rates of Ni (FIG. 4A) and Ni-germanide (FIG. 4B) using HCl:H₂O etch compositions of different concentrations;

FIGS. 5A and 5B are graphs that illustrate the etch rate of Ni (FIG. 5A) and Ni-germanide (FIG. 5B) as a function of temperature using an HCl:H₂O (1:3) composition;

FIG. 5C is a graph that illustrates an Arhennius plot for selective etching of Ni using an HCl:H₂O (1:3) composition;

FIGS. 5D and 5E are graphs that illustrate the etch rate of Ni (FIG. 5D) and Ni-germanide (FIG. 5E) as a function of temperature using an HCl:H₂O (1:7) composition;

FIGS. 6A and 6B are graphs that illustrate the etch rate of Ni (FIG. 6A) and Ni-germanide (FIG. 6B) as a function of temperature using an HCl:H₂SO₄:H₂O (1:0.5:3) composition;

FIG. 6C is a graph of an Arhennius plot that illustrates selective etching of Ni using an HCl:H₂SO₄:H₂O (1:0.5:3) composition;

FIG. 7A and 7B are graphs that illustrate the etch rate of Ni (FIG. 7A) and Ni-germanide (FIG. 7B) using HBr:H₂O etch compositions of different HBr concentrations;

FIG. 8A and 8B are graphs that illustrate the etch rate of Ni (FIG. 8A) and Ni-germanide (FIG. 8B) using HF:H₂O compositions of different HF concentrations; and

FIG. 9A-9C are SEM pictures that illustrate Ni-germanide surfaces that have been subjected to an HCl:H₂O (1:3) composition at different temperatures.

### DETAILED DESCRIPTION

The following description discusses various embodiments related to the formation of self-aligned germanides, including chemical compositions and methods for the formation of self-aligned germanides, such as on a germanium layer, or on a semiconductor substrate. Generally, such self-aligned germanides may be formed by depositing a layer of metal over a substrate and a germanium region, heating the structure to form a compound of the metal and the germanium and selectively removing unreacted metal, e.g. using a selective etching technique. One such selective etching technique is performed using a chemical composition that includes one or more hydrohalides. Various embodiments of chemical compositions that may be used to remove unreacted metals will be described below. Further, various methods for forming self-aligned germanides using such chemical compositions will also be described. It will be appreciated that there are numerous variations and modifications of these embodiments that are possible. Accordingly, the description of the various embodiments should not be deemed to limit the scope of the invention, which is defined by the claims.

Compositions of Chemical Solutions for Forming Self-Aligned Germanides

Compositions that substantially and selectively remove unreacted metal or metals from germanium layers, germanide layers and/or dielectric layers without substantially adversely affecting those layers are disclosed. The term “selective removal of unreacted metal” or “selective etching of unreacted metal”, and the like, refer to the substantial removal of such unreacted metal from a support (e.g., underlying) layer (e.g. a germanide layer) without substantially affecting (etching) the support layer. The term “substantial” or “substantially”, in reference to the removal (etching) of unreacted metal(s), means that more than 95% of the metal layer is removed, more than 98% of the metal layer is removed, or 99% or more of the metal is removed.

An embodiment of a chemical composition that may be used for this purpose comprises one or more hydrohalide(s). The one or more hydrohalides may be selected from the group consisting of HF, HCl, HBr and HI. The chemical composition may also further comprise H₂SO₄. In certain situations, a solution of NH₄0H and/or a solution of H₃PO₄ may also be added to the chemical composition. The chemicals used to prepare such chemical compositions are dilutions that are present in commercially available hydrohalide solutions. Such solutions are commonly used in other areas of VLSI (Very Large Scale Integration) processing. For example, an HCl starting solution may be a 37 wt. % concentrated solution, an H₂SO₄ starting solution may be a 95-97 wt. % concentrated solution, an HF starting solution may be a 49 wt. % concentrated solution and an HBr starting solution can be a 48 wt. % concentrated solution.

The concentration of the different chemical elements in the compositions described herein can be expressed as an x:y ratio or an x:y:z ratio where x, y and z are real numbers and refer to volumetric portions for each component. For example, an HCl:H₂O (1:3) composition means a composition consisting of 1 volumetric part of an HCl solution (such as the HCl solution described above) with 3 volumetric parts of H₂O mixed together. The concentration of the different components in the compositions described herein may also be expressed in terms of wt. %.

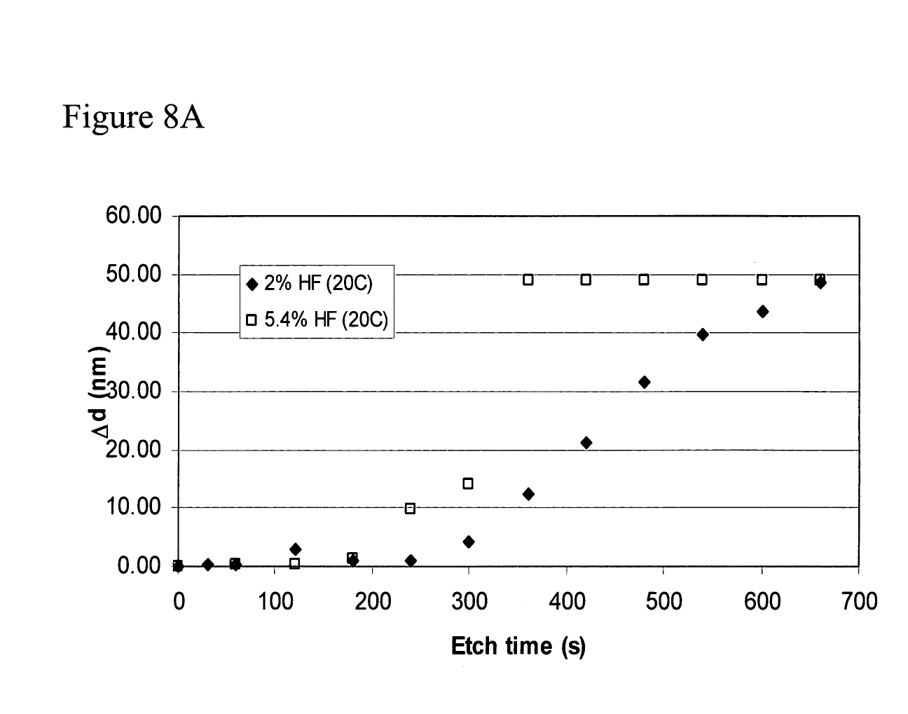

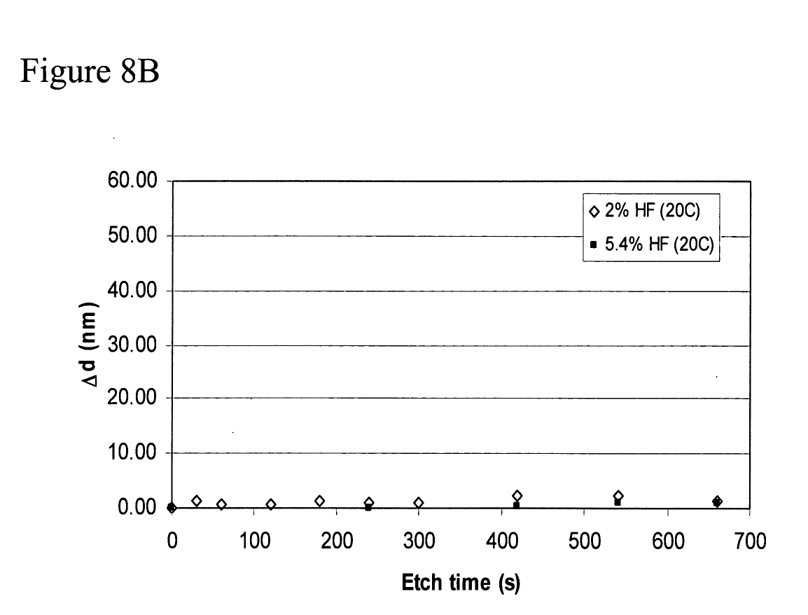

In one embodiment, a composition for selectively removing one or more metals from a germanium layer, a germanide layer and/or a dielectric layer may include less than about 25 wt. % of HF based on the total weight of the composition, less than about 12 wt. %, or less than about 6 wt. %. Referring to FIGS. 8A and 8B, graphs are shown that illustrate the etch rate of Ni (FIG. 8A) and Ni-germanide (FIG. 8B) using HF:H₂O etch compositions with different HF concentrations. Substantially all of the unreacted Ni is removed within 360 seconds with an HF:H₂O composition having a 1:9 ratio. It will be appreciated that HF would normally not be used when the dielectric material is SiO₂, as HF is reactive with (etches) SiO₂.

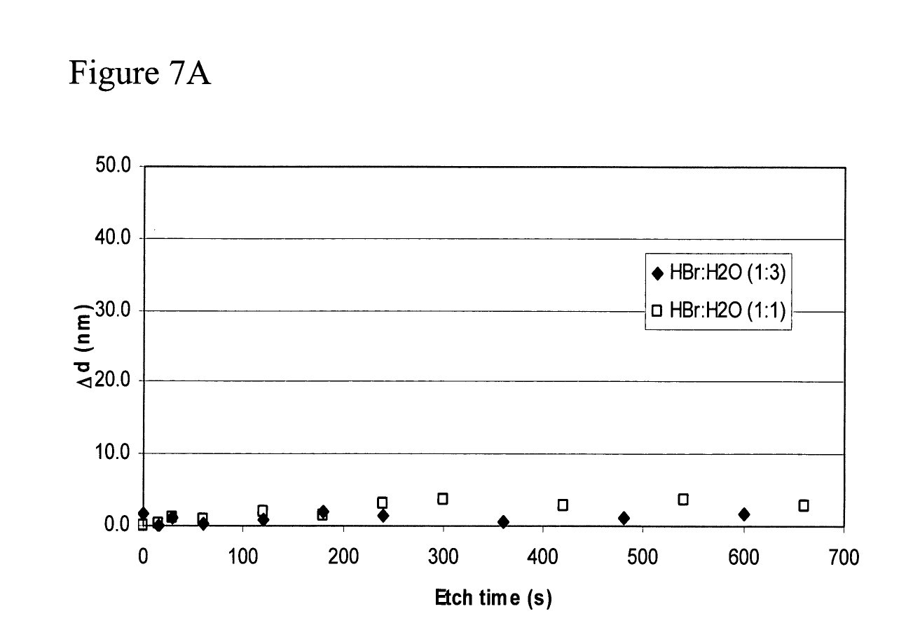

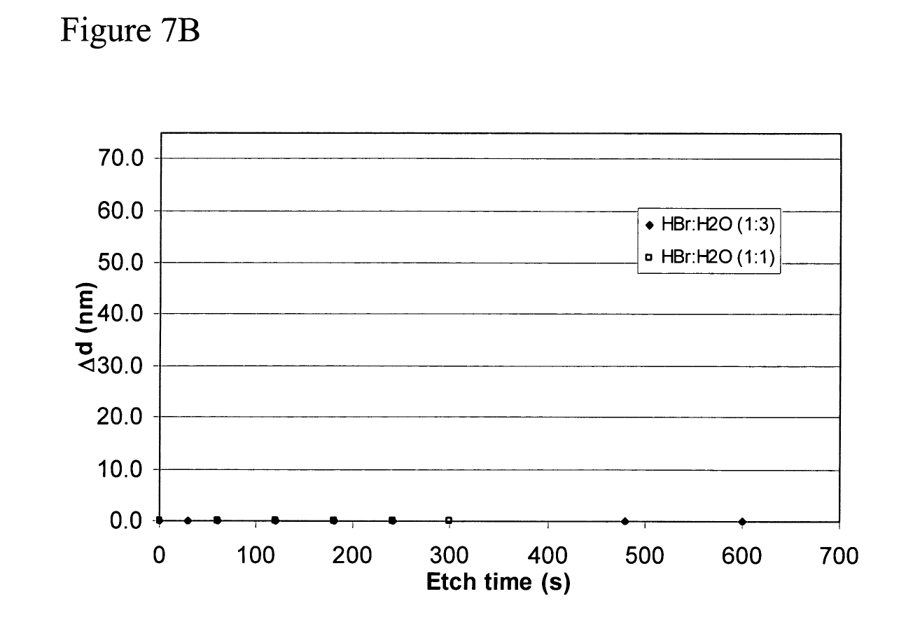

In another embodiment, an alternative composition for selectively removing one or more metals from a germanium layer, a germanide layer and/or a dielectric layer includes less than about 48 wt. % of HBr based on the total weight of the composition, less than about 32 wt. %, or less than about 24 wt. %. Referring to FIGS. 7A and 7B, graphs are shown that illustrate the etch rate of Ni (FIG. 7A) and Ni-germanide (FIG. 7B) using HBr:H₂O etch compositions with different HBr concentrations. As shown, the etch rate of Nickel is relatively slow. However, those skilled in this area would understand that higher concentrations of HBr and higher temperatures would increase the etch rates from those shown in FIGS. 7A and 7B.

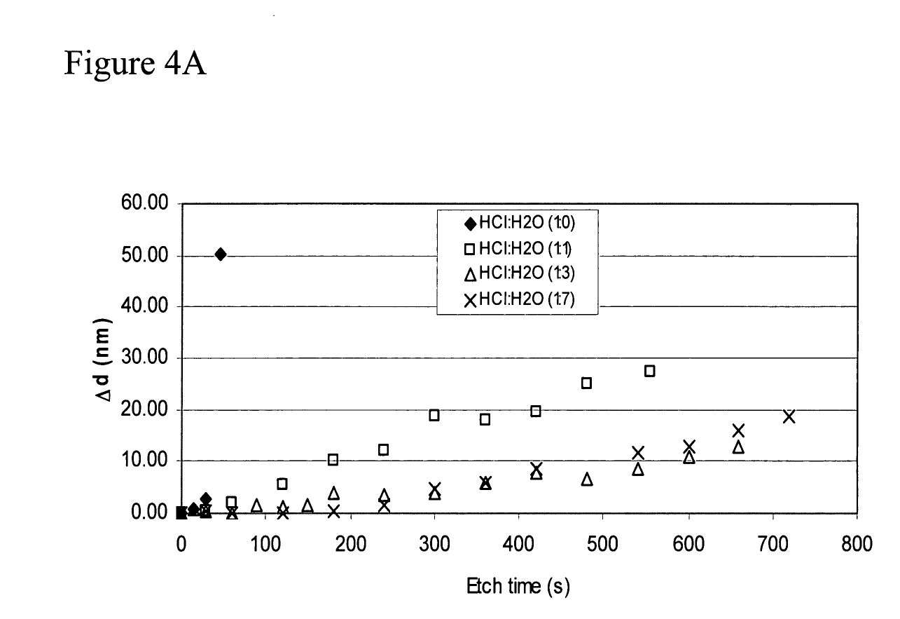

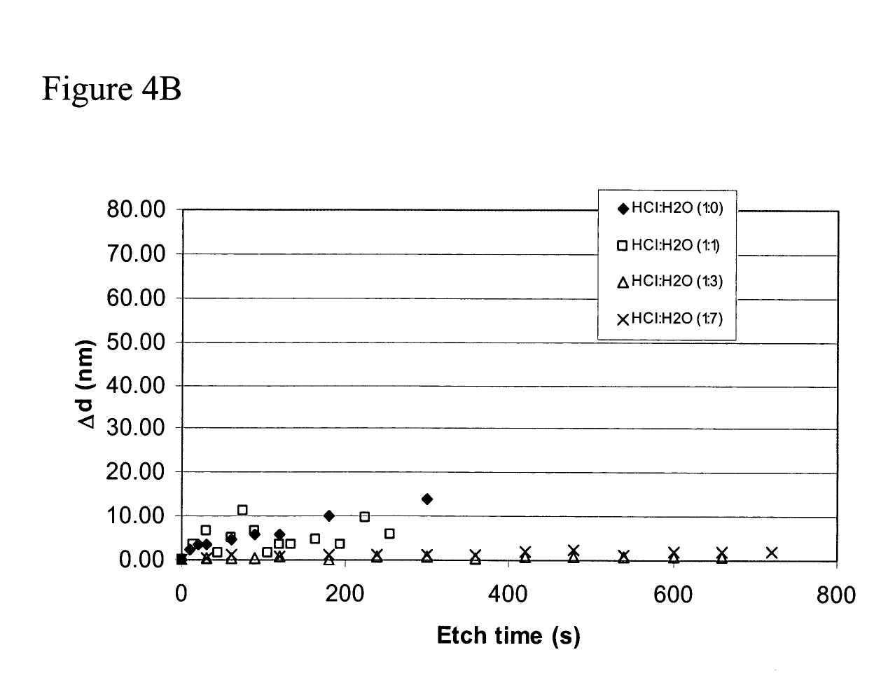

In still another embodiment, a composition for selectively removing one or more metals from a germanium layer, a germanide layer and/or a dielectric layer includes less than about 20 wt. % of HCl based on the total weight of the composition, less than about 15 wt. %, or less than about 10 wt. %. Referring to FIGS. 4A and 4B, graphs are shown that illustrate the etch rate of Ni (FIG. 4A) and Ni-germanide (FIG. 4B) using HCl:H₂O etch compositions with different HCl concentrations.

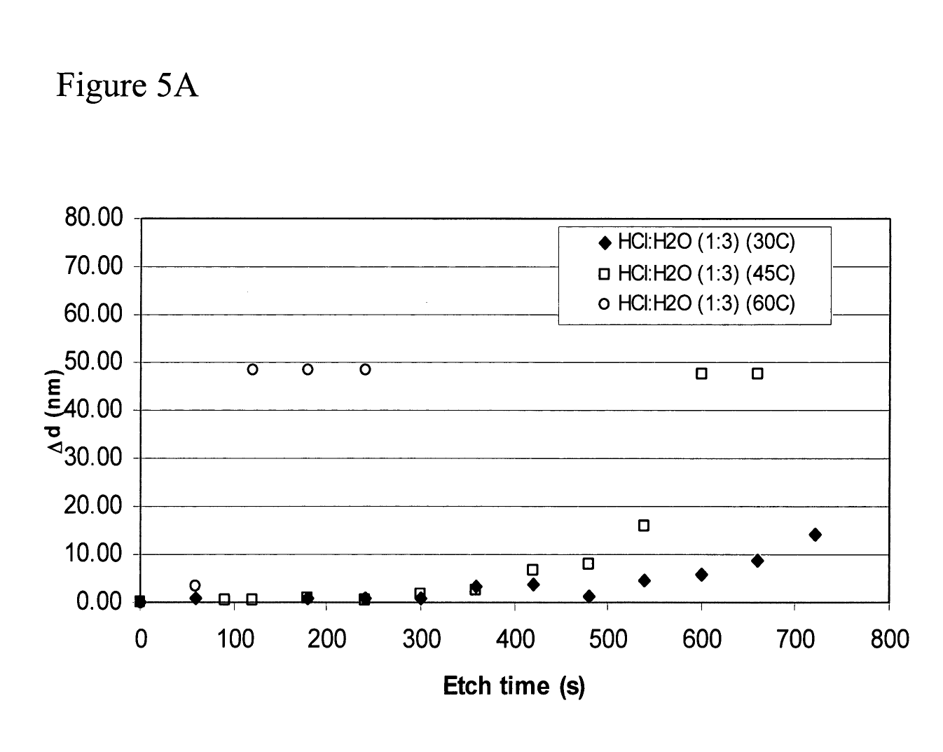

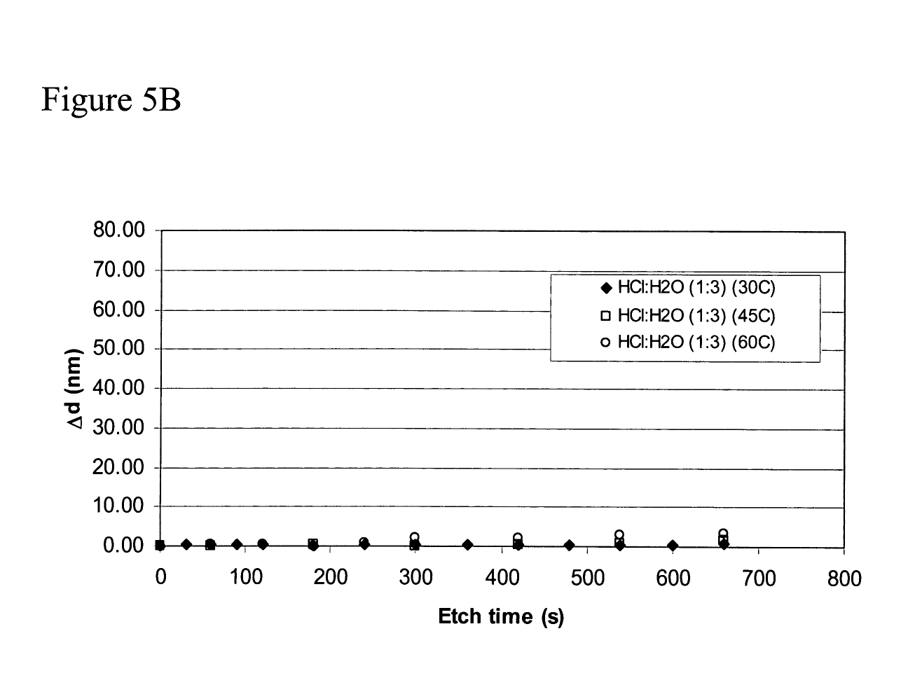

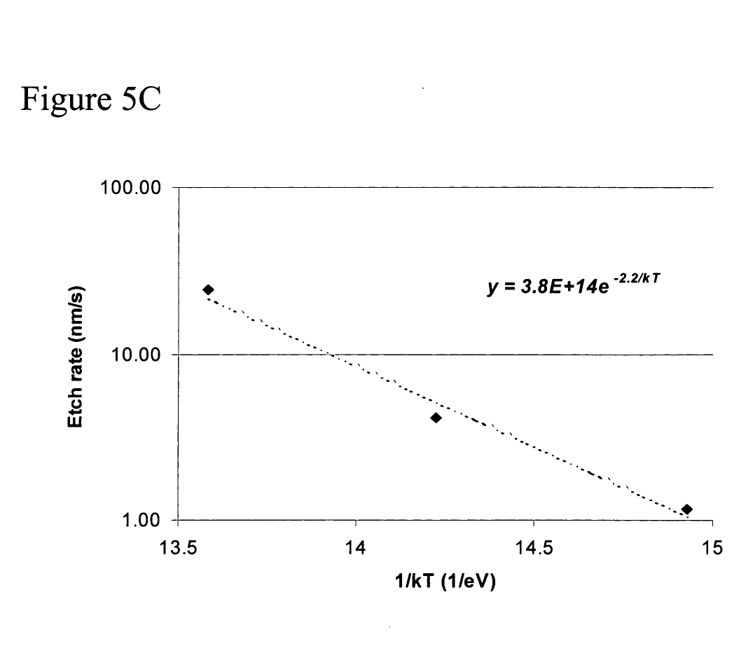

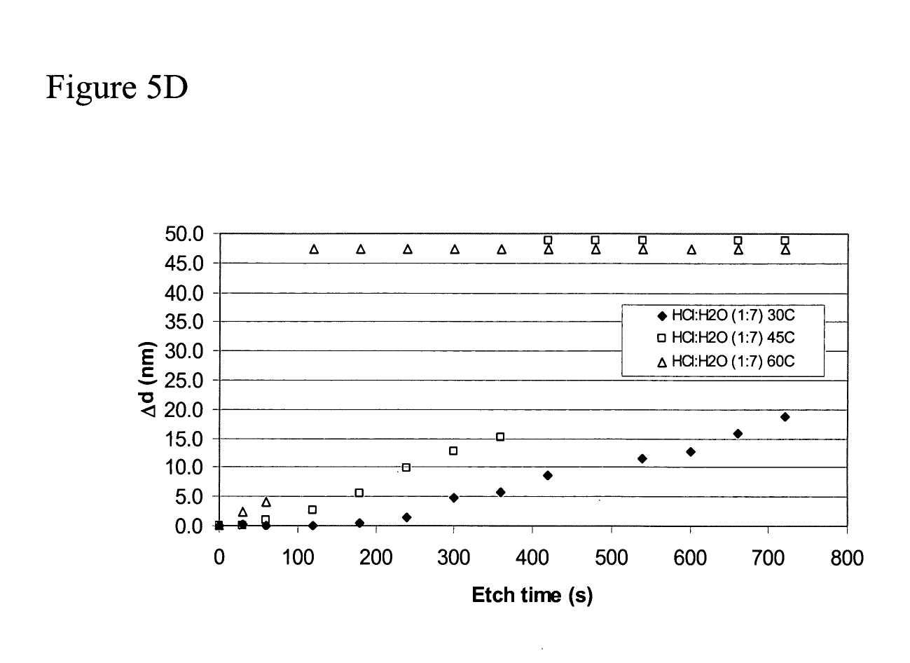

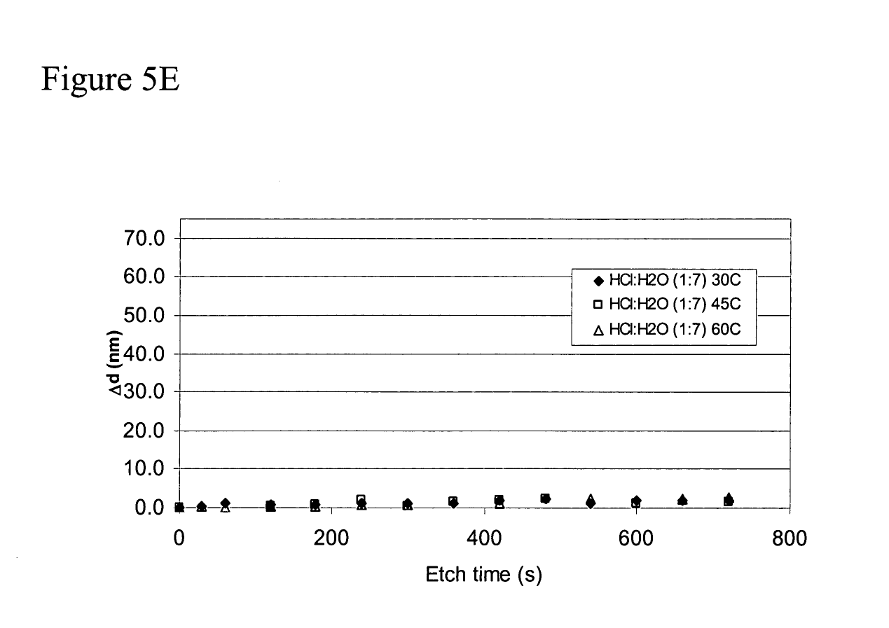

Referring to FIGS. 5A and 5B, graphs are shown that illustrate the etch rate of Ni (FIG. 5A) and Ni-germanide (FIG. 5B) as a function of temperature in an HCl:H₂O (1:3) composition. FIG. 5C shows an Arhennius plot of the selective etching of Nickel with an HCl:H₂O (1:3) composition. The reaction when the metal is removed from the surface of the sample can be characterized by the activation energy Ea. The rate (r) of the reaction in which the metal is etched and dissolved in the etching composition may be expressed by the following equation:

$$r = A exp ( \frac{- {E}_{a}}{kT} )$$

Taking into account the temperature dependence of the reaction, it may be inferred that a high temperature will result in more dissolved metal in a given time period when −Ea<0. If −Ea>0, a lower temperature will result in more dissolved metal in a given time period. By plotting ln(r) versus T, a straight line is obtained in an ideal case, where the slope is equal to the activation energy. In this case (FIG. 5C), the value for Ea is 2.2 eV.

In another embodiment, a diluted and heated HCl:H₂O mixture is used as an etching composition for the selective etching of Ni over Ni-germanide without substantially attacking the substrate or dielectric material. In a specific application, the etching composition includes 1 part HCl and 7 parts H₂O and is heated to increase the etch rate of Nickel. The temperature of the composition may be between about 50° and about 75° C., such as 70° C. In empirical testing, the use of an HCl:H₂O composition with a volumetric ratio of 1:7, at 60° C., removes substantially all unreacted Ni in about 120 seconds for a specific structure (with an initial thickness of 50 nm). This result is substantially the same as the etching rate with a 1:3 (HCl:H₂O) mixture for removal of Ni (e.g., unreacted Ni). However, with respect to etch selectivity: the 1:7 etch mixture has a much higher selectivity. For example, the etch selectivity of the 1:7 (HCl:H₂O) etch composition is 101 and the etch selectivity of the 1:3 (HCl:H₂O) etch composition is 78. In this context, etch selectivity may defined as the etch rate of unreacted metal (e.g., Ni) in nm/min. as compared to the etch rate of metal-germanide (e.g., Ni—Ge) in nm/min.

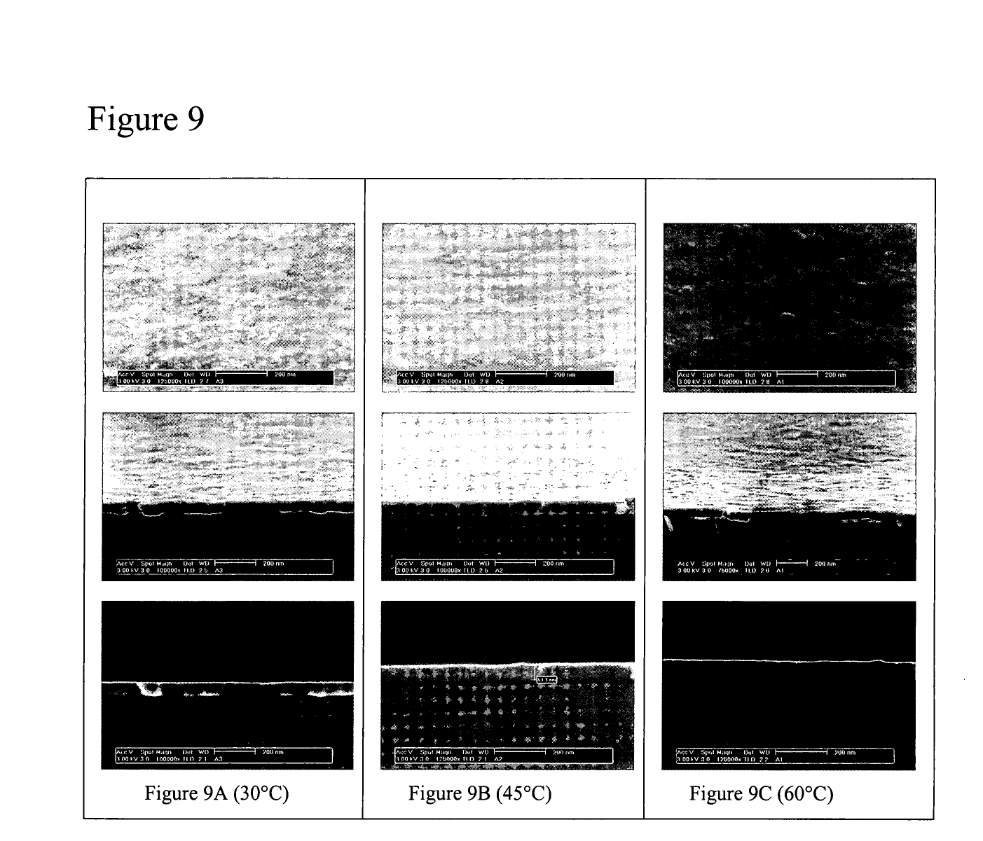

FIGS. 5D and 5E, are graphs that illustrate the etch rate of Ni (FIG. 5D) and Ni-germanide (FIG. 5E) as a function of temperature using an HCl:H₂O (1:7) composition. The Ni-germanide surface is not substantially damaged due to exposure to heated HCl solutions. For example, FIGS. 9A, 9B and 9C are SEM pictures that illustrate Ni-germanide surfaces that have been subjected to HCl:H₂O 1:3 etch compositions at different temperatures. Specifically, FIG. 9A shows a Ni-germanide surface subjected to an HCl:H₂O 1:3 etch composition at 30° C., FIG. 9B shows a Ni-germanide surface subjected to an HCl:H₂O 1:3 etch composition at 45° C. and FIG. 9C shows a Ni-germanide surface subjected to an HCl:H₂O 1:3 etch composition at 60° C. As shown in FIGS. 9A-9C, no substantial damage to the NiGe surface was observed. While the NiGe surfaces shown in FIGS. 9A-9C were dipped in the etch compositions for 120 seconds, it is noted that even longer contact times did not substantially affect the NiGe surface.

In yet another embodiment, a composition for selectively removing one or more metals from a germanium layer, a germanide layer and/or a dielectric layer may also include (e.g., in combination with one of the compositions described above) less than about 50 wt. % of H₂SO₄, less than about 30 wt. % of H₂SO₄, or less than about 20 wt. % of H₂SO₄. As one example, a small amount of H₂SO₄ (e.g. less than 20 wt. %) is added to an HCl solution. The resulting composition may be used at temperatures lower than 50° C., such as at room temperature. Compared to an HCl:H₂O composition that is also used at room temperature, compositions that further include H₂SO₄ result in a higher etch rate of unreacted Ni. Further, there is not a substantial difference in etch selectivity. Such an HCl:H₂SO₄:H₂O composition may have a volumetric ratio of HCl to H₂SO₄ between 1:0.1 and 1:1, such as 1:0.5. Similarly, a particular HCl:H₂SO₄:H₂O composition has a volumetric ratio of 1:0.5:3. This composition may be used to remove metal at temperatures between about 18° C. and about 50° C. It will be appreciated that at higher temperatures, e.g. 70° C., H₂SO₄ would etch NiGe. That is, the HCl:H₂SO₄:H₂O (1:0.5:3) composition loses its selective etching properties at elevated temperatures.

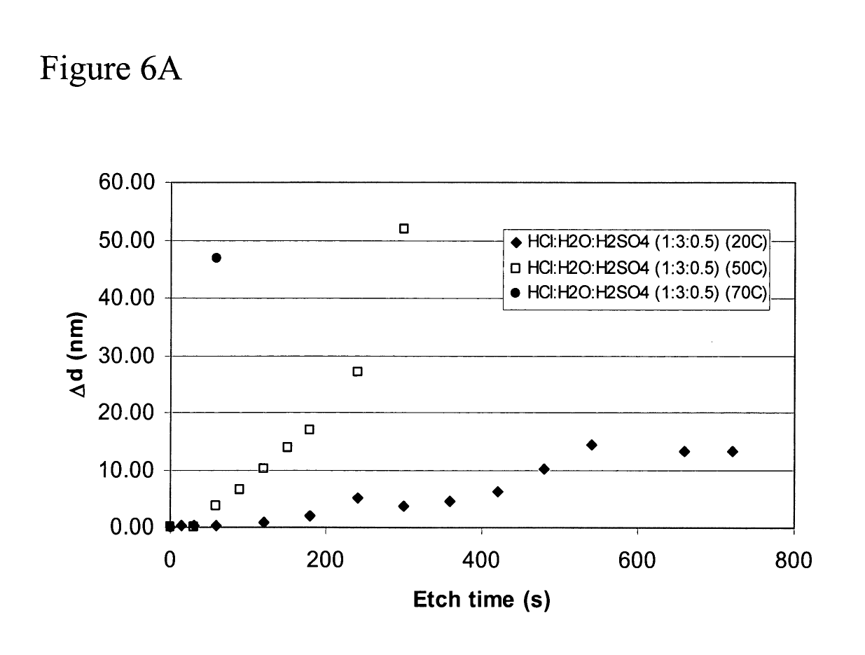

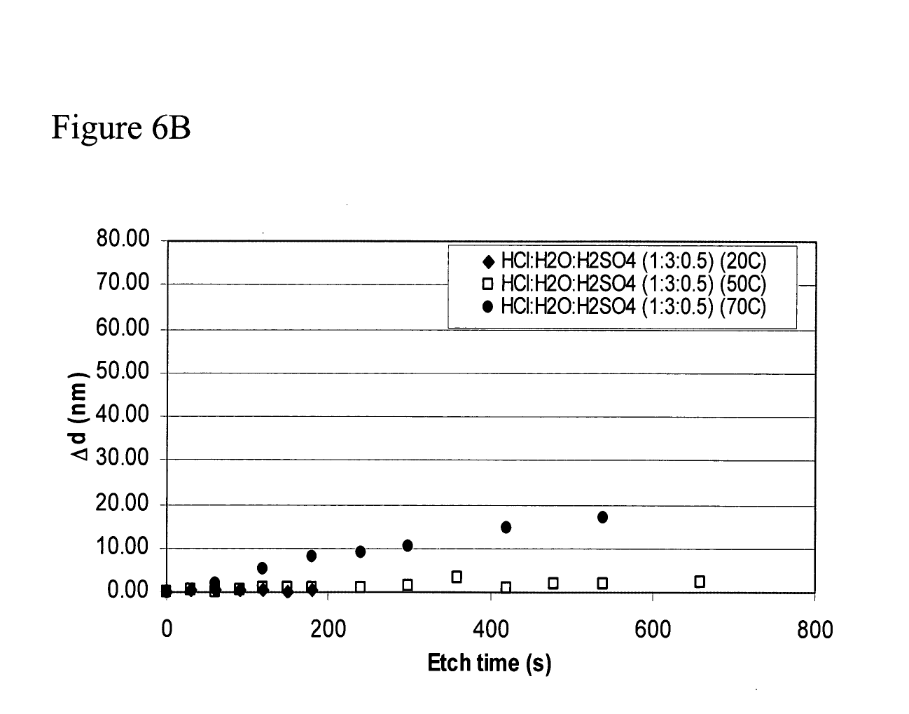

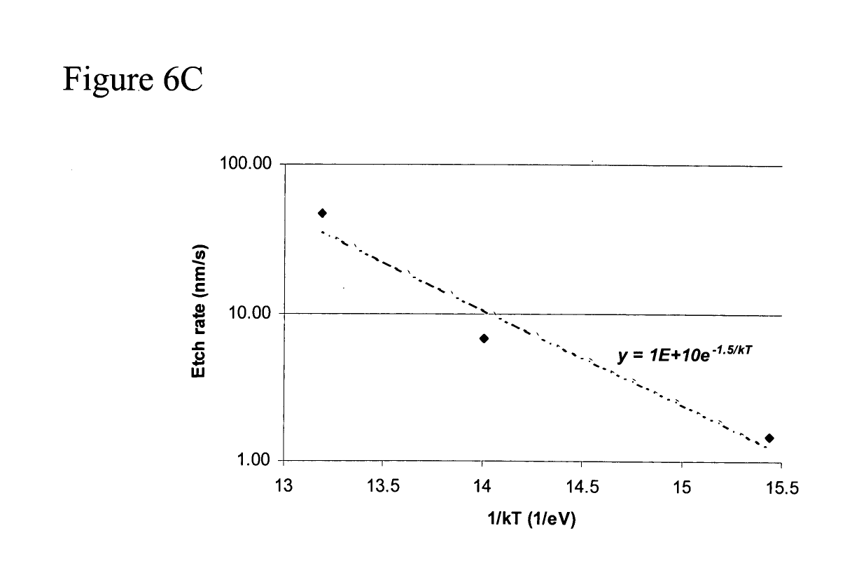

Referring to FIGS. 6A and 6B, graphs are shown that illustrate the etch rate of Ni (FIG. 6A) and Ni-germanide (FIG. 6B) as a function of temperature in such an HCl:H₂SO₄:H₂O (1:0.5:3) composition. Substantially all of the unreacted Ni (with an initial thickness of 50 nm) is removed after 60 sec. when etched at a temperature of 70° C. However, compared to FIG. 5B, etching of the Ni-germanide occurs due to the presence of higher temperature (70° C.) H₂SO₄, which is undesirable. FIG. 6C shows an Arhennius plot that illustrates the selective etching of Nickel with an HCl:H₂SO₄:H₂O (1:0.5:3) composition. The value for Ea in this situation is 1.5 eV, which is lower than the Ea value obtained with an HCl:H₂O (1:3) etch mixture. While certain etching compositions have been described above, it will be appreciated that any number of other compositions including one or more hydrohalides in various concentrations, with or without the addition of H₂SO₄ and/or other components are possible.

Methods for Forming Self-Aligned Germanides

Compositions, such as those described above, may be used for selectively removing unreacted metal(s) from a germanium layer, a germanide layer and/or a dielectric layer. Embodiments of such methods are now described.

In one embodiment for forming a self-aligned germanide, a composition including one or more hydrohalides is contacted with unreacted metal(s) at a temperature between about 20° C. and about 100° C., between about 50° C. and about 75° C., or between about 60° C. and about 70° C. The composition may further include the addition of H₂SO₄ but as described above, compositions including H₂SO₄ are typically not heated due to the loss of etch selectivity to germanium at higher temperatures.

The method includes providing a substrate having at least one region in which germanium is exposed. Metal, such as Ni, is deposited over at least the exposed germanium. The substrate is then heated to form a germanide. After forming the germanide, the unreacted metal is removed by contacting the substrate with a chemical composition, such as the compositions described above (e.g., including one or more hydrohalides, with or without the addition of H₂SO₄). The unreacted metal is selectively removed from the germanide, the substrate and/or dielectric materials that are present on the substrate.

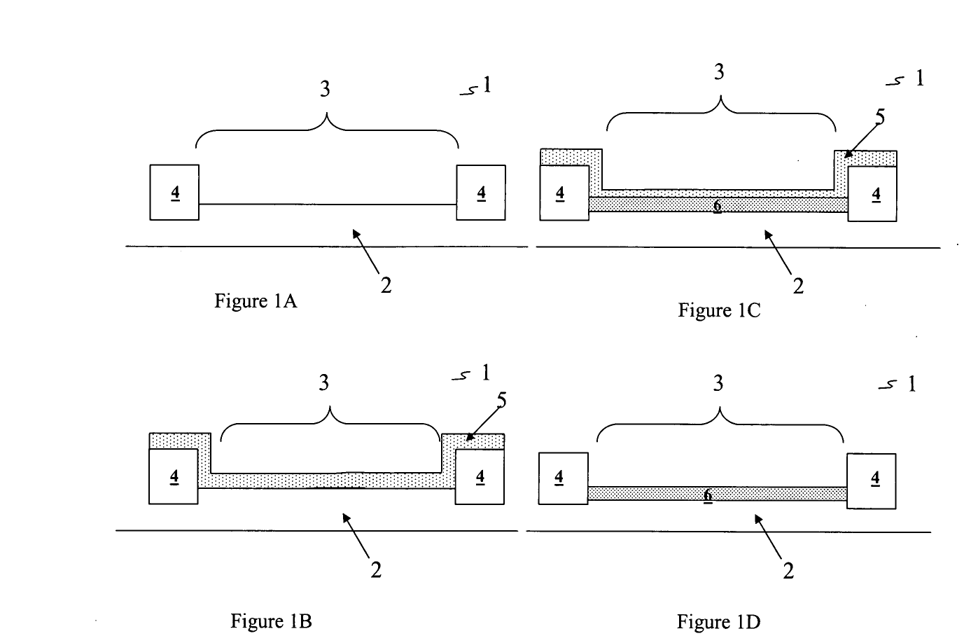

Referring to FIGS. 1A-1D, cross-sectional diagrams are shown that illustrate a process flow for forming self-aligned germanides. As shown in FIG. 1A, a substrate 1 is provided which includes at least one region 3 formed in a germanium layer 2. The substrate 1 may be a bulk germanium wafer, in which case layer 2 is the bulk itself. Alternatively, the substrate 1 may be a germanium-on-insulator (GOI) wafer in which case the layer 2 is a germanium layer formed on a dielectric layer on top of the substrate 1. The germanium region 3 may also be formed by selectively depositing germanium on the substrate 1, at least within the region 3. More generally, the substrate 1 can take the form of any material on which such a germanium region 3 can be formed.

The germanium layer 2 can be a continuous layer that at least partially extends over the substrate 1 or, alternatively, the germanium layer 2 can be divided into separate regions 3. These regions 3 can then be insulated from other regions by field regions 4. The field regions 4 can be formed by etching grooves into the substrate 1 and filling the grooves with a dielectric material, such as an oxide. This insulation method is also known as shallow-trench-insulation (STI). As illustrated in FIG. 1B, a layer 5 of a metal, such as Ni, is deposited over the region 3 and the field regions 4. Within region 3 the deposited metal is in contact with germanium.

As illustrated by FIG. 1C, a heating step is performed that causes the metal 5 to react with the exposed germanium 3 to form a germanide 6 (a compound layer of the germanium 2 and the metal layer 5) at the interface between the germanium and the metal. As only part of the metal 5 reacts, unreacted metal 5 remains on at least the field regions 4, and may also remain on the germanide 6. As illustrated by FIG. 1D, substantially all of the unreacted metal 5 is removed by a selective wet etch, such as an etch using a chemical composition including one or more hydrohalides (which may also further include H₂SO₄), as were described above. This etch leaves the germanide layer 6 in region 3. The chemical composition is selective to at least the germanide layer 6. However, it is also desirable that the chemical composition also doesn't substantially affect the dielectric material of the field regions 4 and/or the germanium of the substrate 1, e.g. by forming GeₓO_{y} when in contact with the germanium.

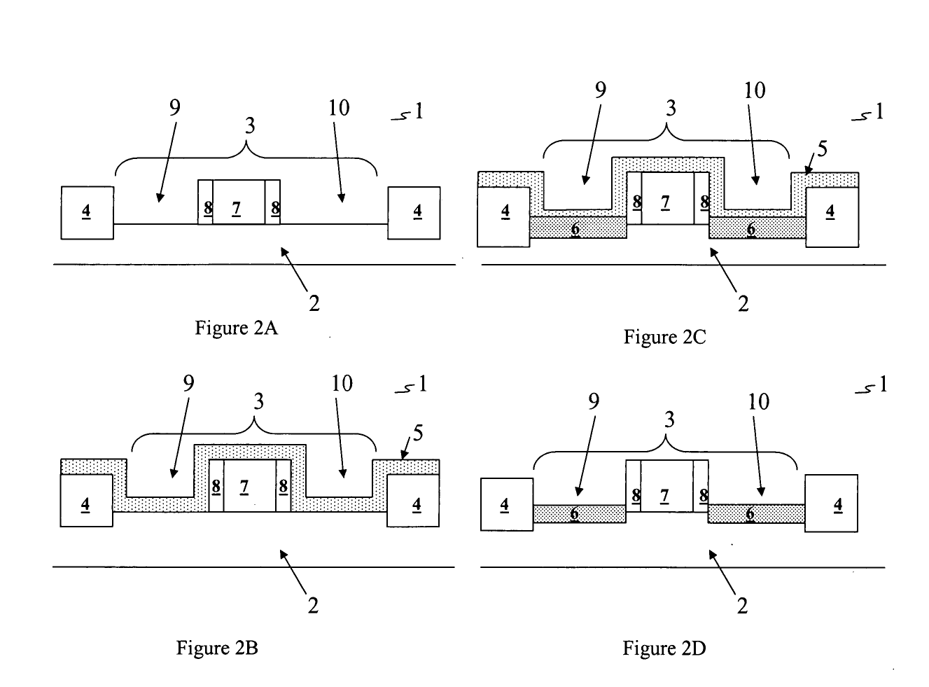

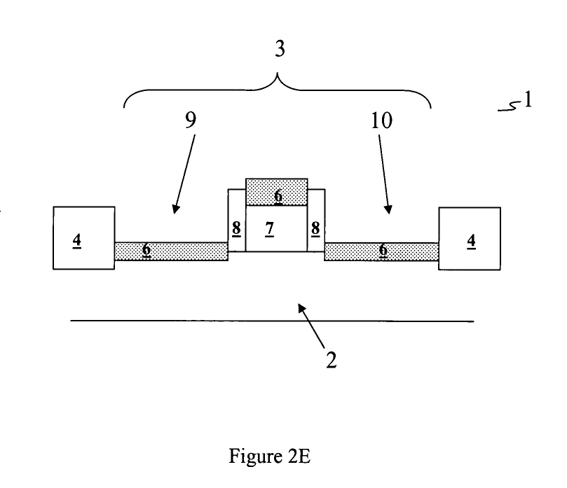

FIGS. 2A-2E illustrate another embodiment, which differs from the embodiment illustrated in FIGS. 1A-1D, in that a structure is present within region 3, as illustrated by FIG. 2A. This structure may be a gate electrode, such as in the case of a unipolar transistor (e.g., a MOSFET (metal-oxide-semiconductor field effect transistor)). The gate electrode in FIG. 2A includes a conductive material 7 that is surrounded by spacers 8. The spacers 8 are formed from a dielectric material. On opposite sides of this gate, a source region 9 and a drain 10 region are formed in the germanium layer 2. In the case of a bipolar transistor, this structure may be an emitter 7 and on opposite sides of the emitter 7 an external base region 9, 10 can be formed. The emitter 7 is insulated form the external base 9, 10 by the dielectric material 8. The dielectric material 8 may be an oxide, a nitride, an oxynitride such as SixOyNx where x+y+z≦1, a silicon-carbide SiC or a siliconoxycarbide SixOyCx where x+y+z≦1, as some examples.

As illustrated in FIG. 2B, a layer 5 of a metal, such as Ni, is deposited over region 3 (the regions 9, 10 and the structure 7, 8). The layer 5 also overlies the field regions 4. Within the region 3, the deposited metal layer 5 is in contact with germanium. As illustrated by FIG. 2C, a heating step is performed which causes the metal layer 5 to react with the exposed germanium 3 to form a germanide 6 at the interface between the germanium and the metal. As only part of the metal layer 5 reacts, excess metal remains on top of the germanide 6 and on the field regions 4. As illustrated by FIG. 2C, germanide is not formed on top of layers 7 and 8.

As shown in FIG. 2D, substantially all unreacted metal of the layer 5 is removed by a selective wet etch, as has been previously described, which leaves the germanide layer 6 in region 3. The etch composition is selective to at least the germanide layer 6. However, it is also desirable that the etch composition also doesn't substantially affect the dielectric material of the field regions 4, the dielectric material 8 of the spacers and/or the germanium layer. The germanide is only formed in the regions 9 and 10 in which germanium was in contact with the metal layer 5.

As shown in FIG. 2E, if the structure 7 is formed from germanium, the germanide layer 6 is also formed on top of the structure 7. In the case of an MOS transistor formed on a GOI layer 2 having a germanium gate 7, a NiGe layer 6 can be formed in the source region 9, the drain region 10 and on the gate 7. After forming the germanide layer 6, substantially all the unreacted metal (e.g., Ni) is removed from the substrate 1 using a single wet etch step that employs a chemical composition such as those described above. Thus, a self-aligned NiGe germanide is formed by this process.

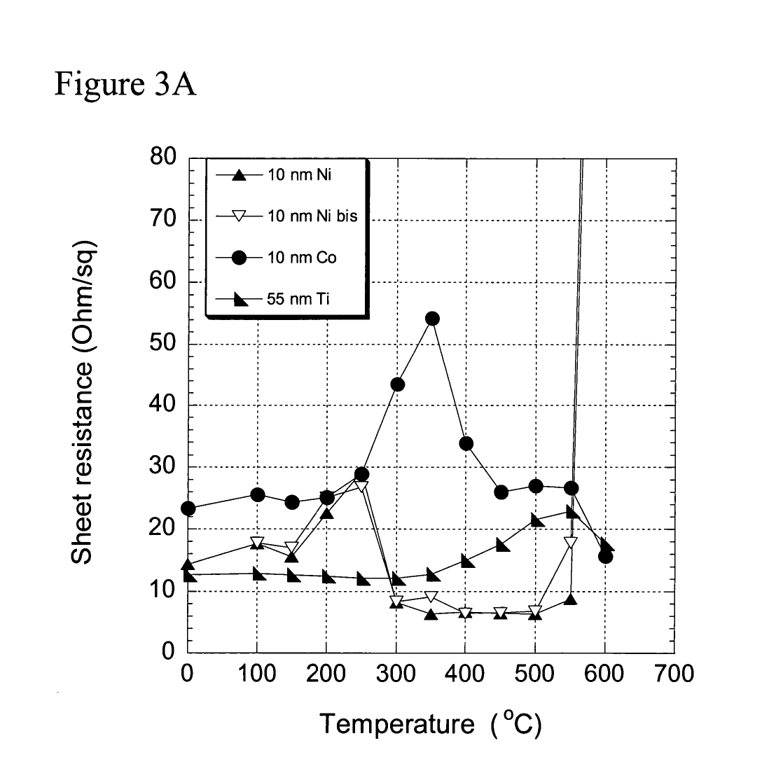

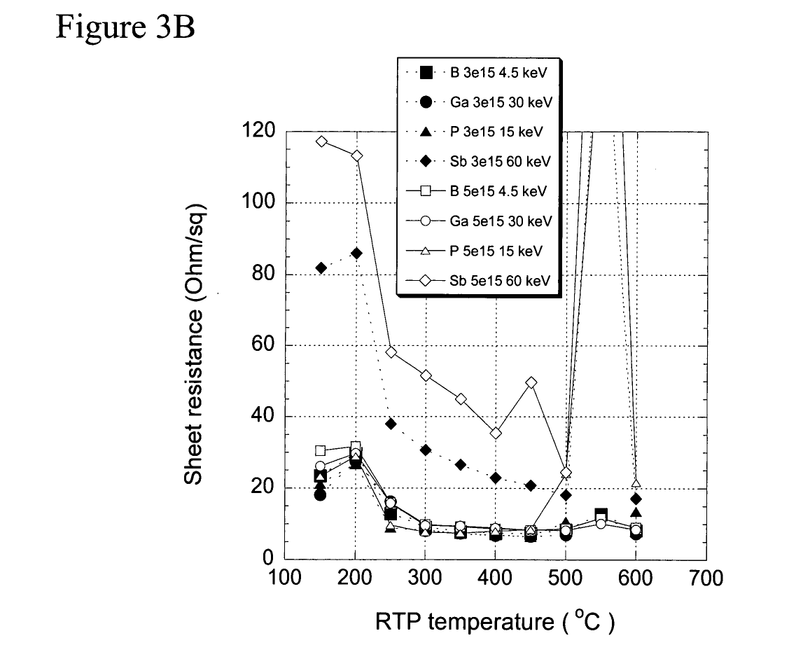

In another embodiment, a germanium layer 2 and either 10 nm of Ni, 10 nm of Co or 55 nm of Ti is deposited. The stack of germanium 2 and metal is then annealed for 30 sec. using rapid thermal annealing (RTA) in an inert gas atmosphere. The corresponding sheet resistance for stacks annealed at various temperatures is shown in graph form in FIG. 3A for the case of Ni, Co or Ti deposited on undoped germanium. FIG. 3B shows similar data for Ni deposited on germanium, doped with either Boron (B), Gallium (Ga), Phosphorus (P) or Antimony (Sb). The implant conditions (species, dose, energy) are indicated in FIG. 3B.

In yet another embodiment, a layer of Ni is deposited on a germanium layer. The stack of Ni and Ge is heated to a temperature between 300° C. and 600° C., such as between 350° C. and 450° C. The duration of this heating step is between 30 sec. and 10 minutes, such as between 30 sec. and 2 minutes. As is shown in FIG. 3A, in this temperature range, a low resistive NiGe layer 6 is formed that has a sheet resistance below 10 ohms/square. The unreacted Ni is then selectively removed at room temperature using a wet etch composition, such as one of those described above.

In still another embodiment, a stack of Ni and Ge is heated to a temperature between 150° C. and 200° C. The duration of this heating step is between 30 sec. and 10 minutes, such as between 30 sec. and 2 minutes. FIG. 3A illustrates that in this embodiment, a Ni-rich germanium layer is formed having a sheet resistance between 10 and 20 ohms/square. The unreacted Ni is removed at room temperature using a wet etch composition, as has been previously described. Thereafter, the Ni-rich germanium layer is converted into a NiGe germanide layer by heating the Ni-rich germanium layer to a temperature between 300° C. and 600° C., such as between 350° C. and 450° C. The duration of this heating step is between 30 sec. and 10 minutes, such as between 30 sec. and 2 minutes.

If dielectric materials such as an oxide, a nitride, an oxynitride such as SiₓO_{y}N_{z} where x+y+z≦1, a silicon-carbide SiC or a siliconoxycarbide SiₓO_{y}C_{z} where x+y+z≦1 (e.g., the field regions 4 and the spacers 8 in FIGS. 2A-2D), are present on the substrate 1, the etch composition desirably removes unreacted metal 5 with high selectivity to these dielectric materials. It is also desirable that the chemical etch composition does not include agents that oxidize (e.g., damage) the germanium layer 2. To avoid oxidation of germanium, concentrated H₂SO₄ at higher temperatures is not used because, as is known, concentrated H₂SO₄ oxidizes germanium at elevated temperatures. The wet etch composition can also comprise other additives to improve the etch selectivity or etch rate of the unreacted metal. However, when silicon-oxide dielectrics are employed, the use HF is not desirable as HF is aggressive in etching silicon-oxide.

Semiconductor Devices Comprising Self-Aligned Germanides

The methods described above may be carried out to obtain a semiconductor device that includes regions where a self-aligned germanide is formed by selectively removing unreacted metal using a composition (heated or not) that includes at least one hydrohalide, and may further include H₂SO₄ and/or other components. Such a device is characterized by the fact that no substantial attack of the germanide by the composition is observed and that, for example, more than 99% of the unreacted metal may be removed. Such a semiconductor device may be a MOSFET comprising a source region and a drain region that are formed in a germanium layer and/or with a gate formed in a germanium layer.

### EMPIRICAL EXAMPLES

In the following examples, the etch compositions discussed are dilutions that were prepared from commercially available HCl, HF and H₂SO₄ solutions that are commonly used in VLSI processing. The HCl starting solution used was a 37 wt. % concentration solution, the H₂SO₄ starting solution was a 95-97 wt. % concentration solution and the HF starting solution was a 49 wt. % concentration solution.

### Example 1

### Different HCl:H₂O Compositions and Their Effect on Etching Selectivity and Etch Rate.

Different ratios of HCl:H₂O ranging from 1:0 to 1:7 were tested at room temperature. It was determined that at room temperature, the etching rate for unreacted Ni increased with the HCl concentration. At room temperature, substantially all of the unreacted Ni (with an initial thickness of 50 mn) was removed in less than 60 seconds with an HCl:H₂O composition having a volumetric ratio of 1:0. However, such high concentrations of HCl may attack (even if at very slow rate) the NiGe, as shown in the graph of FIG. 4B.

### Example 2

### Effect of Temperature on Etching Selectivity and Etch Rates.

HCl:H₂O compositions having volumetric ratios of 1:3 and 1:7 were studied. These compositions were used at three different temperatures: room temperature, 45° C. and 60° C. to remove unreacted metal. FIG. 5A is a graph that illustrates the observed etch rates of unreacted Ni (removal of Ni as a function of time) at different temperatures for the 1:3 ratio composition. Substantially all of the unreacted Ni (with an initial thickness of 50 nm) is removed in 120 seconds at a temperature of 60° C., where the etch selectivity to Ni-germanide was 78.

FIG. 5D is a graph that illustrates the etch rates of unreacted Ni (removal of Ni as a function of time) at different temperatures for the 1:7 ratio HCl:H₂O composition. Using this composition, substantially all of the unreacted Ni (with an initial thickness of 50 nm) is removed in 120 seconds at a temperature of 60° C., where the etch selectivity to Ni-germanide was 101.

FIGS. 5B and 5E are graphs that illustrate the etch rate of NiGe with these two etch compositions at different temperatures. FIGS. 9A-9C show SEM pictures of Ni-germanide surfaces subjected to the etch composition of a 1:3 ratio at different temperatures (FIGS. 9A, 9B and 9C respectively corresponding to 30° C., 45° C. and 60° C.) and show that substantially no damage was observed. From this, it may be concluded that for HCl concentrations lower than about 10 wt. %, based on the total weight of the composition, and independent of etch temperature, that Ni is selectively removed (etched) from NiGe. It may be also concluded from the foregoing that the selective etch rate may be improved by heating the etch composition without causing any substantial damage to the NiGe layer.

### Example 3

### Addition of H₂SO₄ to an HCl:H₂O Etching Composition

FIG. 6A is a graph that illustrates the etching of unreacted Ni using an HCl:H₂SO₄:H₂O composition with a volumetric ratio of 1:0.5:3. A comparison FIG. 5A and FIG. 6A demonstrates that the etch rate of unreacted Ni is higher with an HCl:H₂SO₄:H₂O (1:0.5:3) composition than an HCl:H₂O (1:3) composition. Also, as is shown in FIG. 6A, higher temperatures result in higher etch rates of unreacted Ni. However, as is shown in FIG. 6B, an HCl:H₂SO₄:H₂O (1:0.5:3) composition at a temperature higher than about 50° C. is aggressive to NiGe, which is slowly etched.

### Example 4

### Use of HF:H₂O Etching Compositions

Different HF:H₂O compositions with volumetric ratios varying from 1:24.5 to 1:9 were tested. The results for selective removal (or selective etching) of unreacted Ni with an HF:H₂O ratio of 1:24.5 and 1:9 are shown in FIG. 8A. As shown in FIG. 8A, the use of an HF:H₂O composition having a volumetric ratio of 1:9, at room temperature resulted in the removal of substantially all of the unreacted Ni (with an initial thickness of 50 nm) in about 360 seconds. FIG. 8B shows the etching rate of NiGe with the two different HF:H₂O compositions described above. From FIG. 8B, it may be concluded that there is no substantial attack of the germanide.

### Example 5

### Etch Selectivity of HCl:H₂O Mixtures

A lower concentration of HCl (e.g. HCl:H₂O composition having a ratio of 1:7 compared to a ratio of 1:3) showed improved selective removal (e.g., improved etch selectivity) of Ni, as is shown in the graphs of FIG. 4. The etch selectivity of an HCl:H₂O composition with a 1:7 ratio to NiGe is 101 compared to an etch selectivity of 78 for an HCl:H₂O composition with a 1:3 ratio. Table 1 below includes the etch selectivity values for the etch compositions and etch temperatures discussed above:

TABLE 1
Etch Selectivities

| | Etch rate Ni | Etch rate Ni—Ge | |
|---|---|---|---|
| Temperature (° C.) | (nm/min.) | (nm/min.) | selectivity |
| HCl:H₂SO₄:H₂O (1:0.5:3) | | | |
| 20 | 1.48 | 0.20 | 7 |
| 50 | 6.77 | 0.65 | 10 |
| 70 | 46.65 | 1.90 | 25 |
| HCl:H₂O (1:3) | | | |
| 30 | 1.16 | 0.11 | 11 |
| 45 | 4.13 | 0.16 | 26 |
| 60 | 24.25 | 0.31 | 78 |
| HCl:H₂O (1:7) | | | |
| 30 | 1.56 | 0.16 | 10 |
| 45 | 4.06 | 0.18 | 22 |
| 60 | 23.66 | 0.24 | 101 |

1. A chemical composition comprising:
one or more hydrohalides, wherein the composition is used for the removal of unreacted metal from at least one of a germanium layer, a germanide layer and a dielectric material.

2. The composition of claim 1, wherein the one or more hydrohalides are selected from the group consisting of HCl, HF, HI and HBr.

3. The composition of claim 1, wherein a first hydrohalide of the one or more hydrohalides is HCl.

4. The composition of claim 3 wherein the concentration of HCl is less than 37 wt. %.

5. The composition of claim 3 wherein the concentration of HCl is less than 20 wt. %.

6. The composition of claim 3 wherein the concentration of HCl is less than 10 wt. %.

7. The composition of claim 1, further comprising H₂SO₄.

8. The composition of claim 1, wherein the unreacted metal is nickel (Ni).

9. The composition of claim 1, wherein the composition is used to remove the unreacted metal at a temperature between 18° C. and 100° C.

10. The composition of claim 1, wherein the composition is used to remove the unreacted metal at a temperature between 50° C. and 80° C.

11. A method for forming a self-aligned germanide, comprising:
removing unreacted metal from at least one of a germanium layer, a germanide layer and a dielectric material by contacting the unreacted metal with a chemical composition comprising one or more hydrohalides.

12. The method of claim 11, wherein a concentration of the one or more hydrohalides in the chemical composition is less than 37 wt. %.

13. The method of claim 11, wherein the one or more hydrohalides are selected from the group consisting of HCl, HF, HI and HBr.

14. The method of claim 11, wherein a first hydrohalide of the one or more hydrohalides is HCl.

15. The method of claim 14, wherein a concentration of HCl in the chemical composition is less than 37 wt. %.

16. The method of claim 14, wherein the concentration of HCl in the chemical composition is less than 20 wt. %.

17. The method of claim 14, wherein the concentration of HCl in the chemical composition is less than 10 wt. %.

18. The method of claim 11, wherein the chemical composition further comprises H₂SO₄.

19. The method of claim 11, wherein said unreacted metal is nickel.

20. The method of claim 11, wherein a temperature of the chemical composition is between 18° C. and 100° C.

21. The method of claim 11, wherein a temperature of the chemical composition is between 50° C. and 80° C.

22. A semiconductor device comprising a self-aligned germanide from which unreacted metal has been removed by a composition comprising one or more hydrohalides.
